(19) United States
(12) Patent Application Publication
(10) Pub. No.: US 2026/0221399 A1
(43) Pub. Date: Jul. 30, 2026

(54) SUBSTRATE SUPPORT ASSEMBLY, SUBSTRATE PROCESSING APPARATUS, AND SUBSTRATE PROCESSING METHOD

(71) Applicant: Tokyo Electron Limited, Tokyo (JP)

(72) Inventors: Akira NAGAYAMA, Miyagi (JP); Atsushi KAWABATA, Miyagi (JP); Ryosuke SAITO, Miyagi (JP)

(73) Assignee: Tokyo Electron Limited, Tokyo (JP)

(21) Appl. No.: 19/578,606

(22) Filed: Mar. 25, 2026

Related U.S. Application Data
(63) Continuation of application No. PCT/JP2024/033938, filed on Sep. 24, 2024.

(30) Foreign Application Priority Data
Oct. 3, 2023 (JP) 2023-172027
May 13, 2024 (JP) 2024-077973

(51) Int. Cl. H01J 37/32

(52) U.S. Cl. CPC H01J 37/32724

(57) ABSTRACT

Disclosed is a substrate support assembly. A base of the substrate support assembly includes a flow path. The first gas supply is connected to the first container. The first gas supply is configured to supply a first gas to the first container for supplying a first heat transfer medium in the first container to the flow path via at least one first pipe. The second gas supply is connected to the second container. The second gas supply is configured to supply a second gas to the second container. The heat transfer medium supply further includes at least one third pipe and a valve.

### CROSS-REFERENCE TO RELATED APPLICATIONS

This application is a continuation application of PCT Application No. PCT/JP2024/033938, filed on Sep. 24, 2024, which claims the benefit of priority from Japanese Patent Application No. 2024-077973, filed on May 13, 2024, and Japanese Patent Application No. 2023-172027, filed on Oct. 3, 2023. The entire contents of the above listed PCT and priority applications are incorporated herein by reference.

### BACKGROUND

### Field

Exemplary embodiments of the present disclosure relate to a substrate support assembly, a substrate processing apparatus, and a substrate processing method.

### Description of the Related Art

A plasma processing apparatus is used in plasma processing of a substrate. A plasma processing apparatus disclosed in Japanese Unexamined Patent Publication No. 2001-110885 includes a chamber and a suction device. The suction device suctions the substrate. A refrigerant flow path is formed inside the suction device. A refrigerant is supplied to the refrigerant flow path from a refrigerant supply port. The refrigerant supplied to the refrigerant flow path is discharged from a refrigerant discharge port.

### SUMMARY

In one exemplary embodiment, a substrate support assembly includes a base, a substrate support on the base, and a heat transfer medium supply. The base includes a flow path. The heat transfer medium supply is connected to the flow path. The heat transfer medium supply includes a first container, at least one first pipe, a second container, at least one second pipe, a first gas supply, and a second gas supply. The first container is configured to store the heat transfer medium therein. The at least one first pipe is connected between a first end of the flow path and the first container. The at least one second pipe is connected between a second end of the flow path and the second container. The first gas supply is connected to the first container. The first gas supply is configured to supply a first gas to the first container to supply the heat transfer medium in the first container to the flow path via the at least one first pipe. The second gas supply is connected to the second container. The second gas supply is configured to supply a second gas to the second container. The heat transfer medium has a specific gravity greater than a specific gravity of the first gas and a specific gravity of the second gas. The heat transfer medium supply further includes at least one third pipe and a valve. The valve is connected between the first container and the second container via the at least one third pipe.

### BRIEF DESCRIPTION OF THE DRAWINGS

FIG. 1 is a diagram showing a configuration example of a plasma processing system.

FIG. 2 is a diagram showing a configuration example of a capacitively coupled plasma processing apparatus.

FIG. 3 is a diagram schematically showing a substrate support assembly according to one exemplary embodiment.

FIG. 4 is a diagram schematically showing a substrate support assembly according to another exemplary embodiment.

FIG. 5 is a flowchart showing a substrate processing method according to one exemplary embodiment.

FIG. 6 is a diagram schematically showing a substrate support assembly according to still another exemplary embodiment.

FIG. 7 is a plan view of a movable plate according to one exemplary embodiment.

FIG. 8 is a flowchart showing a substrate processing method according to another exemplary embodiment.

### DETAILED DESCRIPTION

Hereinafter, various exemplary embodiments will be described in detail with reference to the accompanying drawings. In the drawings, the same or equivalent portions are denoted by the same reference symbols.

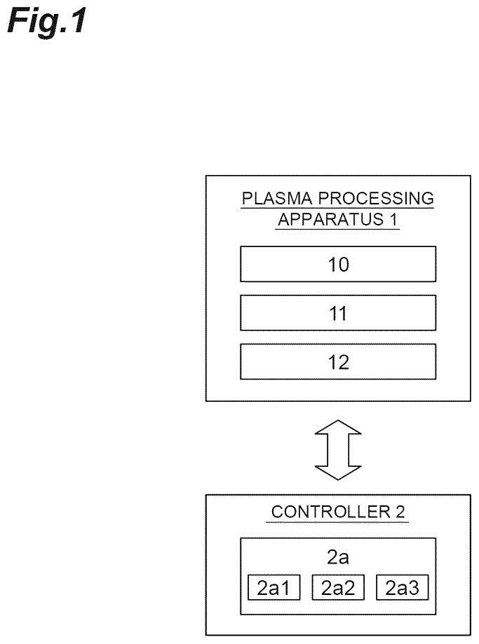

FIG. 1 shows a configuration example of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support assembly 11, and a plasma generator 12. The plasma processing chamber 10 includes a plasma processing space. The plasma processing chamber 10 further includes at least one gas supply port for supplying at least one process gas into the plasma processing space and at least one gas exhaust port for exhausting the gas from the plasma processing space. The gas supply port is connected to a gas supply 20 described later, and the gas exhaust port is connected to an exhaust system 40 described later. The substrate support assembly 11 is disposed in the plasma processing space, and includes a substrate support surface for supporting a substrate.

The plasma generator 12 is configured to generate plasma from at least one process gas supplied into the plasma processing space. The plasma formed in the plasma processing space may be capacitively coupled plasma (CCP), inductively coupled plasma (ICP), electron-cyclotron-resonance (ECR) plasma, helicon wave plasma (HWP), or surface wave plasma (SWP). Further, various types of plasma generators including an alternating current (AC) plasma generator and a direct current (DC) plasma generator may be used. In one embodiment, an AC signal (AC power) used in the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions causing the plasma processing apparatus 1 to perform various steps described in the present disclosure. The controller 2 may be configured to control individual elements of the plasma processing apparatus 1 such that these elements execute the various steps. In one embodiment, the functions of the controller 2 may be partially or entirely incorporated into the plasma processing apparatus 1. The controller 2 may include a processor 2a1, a storage 2a2, and a communication interface 2a3. The controller 2 is implemented by, for example, a computer 2a. The processor 2a1 may be configured to read a program from the storage 2a2, and then perform various control operations by executing the program. This program may be stored in the storage 2a2 in advance, or may be acquired from a medium as needed. The acquired program is stored in the storage 2a2, and then the processor 2a1 reads the program from the storage 2a2 for execution. The medium may be various storage media readable by the computer 2a, or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or combinations thereof. The communication interface 2a3 may communicate with the plasma processing apparatus 1 via the communication line such as a local area network (LAN).

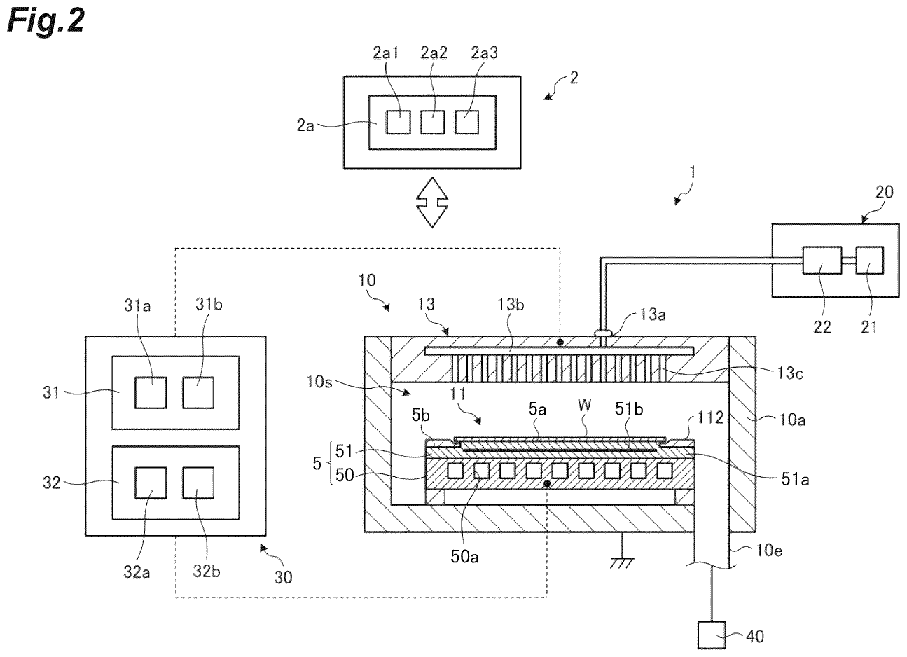

Hereinafter, a configuration example of a capacitively coupled plasma processing apparatus, which is an example of the plasma processing apparatus 1, will be described. FIG. 2 shows the configuration example of the capacitively coupled plasma processing apparatus.

The capacitively coupled plasma processing apparatus 1 includes a plasma processing chamber 10, a gas supply 20, a power supply 30, and an exhaust system 40. Further, the plasma processing apparatus 1 includes a substrate support assembly 11 and a gas introducer. The gas introducer is configured to introduce at least one process gas into the plasma processing chamber 10. The gas introducer includes a showerhead 13. The substrate support assembly 11 is disposed in the plasma processing chamber 10. The showerhead 13 is disposed above the substrate support assembly 11. In one embodiment, the showerhead 13 constitutes at least a part of a ceiling of the plasma processing chamber 10. The plasma processing chamber 10 includes a plasma processing space 10s defined by the showerhead 13, a side wall 10a of the plasma processing chamber 10, and the substrate support assembly 11. The plasma processing chamber 10 is grounded. The showerhead 13 and the substrate support assembly 11 are electrically insulated from a housing of the plasma processing chamber 10.

The substrate support assembly 11 includes a main body 5 and a ring assembly 112. The main body 5 includes a central region 5a for supporting a substrate W and an annular region 5b for supporting the ring assembly 112. A wafer is an example of the substrate W. The annular region 5b of the main body 5 surrounds the central region 5a of the main body 5 in plan view. The substrate W is disposed on the central region 5a of the main body 5, and the ring assembly 112 is disposed on the annular region 5b of the main body 5 to surround the substrate W on the central region 5a of the main body 5. Therefore, the central region 5a is also called a substrate support surface for supporting the substrate W, while the annular region 5b is also called a ring support surface for supporting the ring assembly 112.

In one embodiment, the main body 5 includes a base 50 and a substrate support 51. The substrate support 51 is, for example, an electrostatic chuck. The base 50 includes a conductive member. The conductive member of the base 50 can function as a lower electrode. The substrate support 51 is disposed on the base 50. The substrate support 51 includes a ceramic member 51a and an electrostatic electrode 51b disposed in the ceramic member 51a. The ceramic member 51a includes the central region 5a. In one embodiment, the ceramic member 51a also includes the annular region 5b. Other members surrounding the substrate support 51, such as an annular electrostatic chuck or an annular insulating member, may include the annular region 5b. In this case, the ring assembly 112 may be disposed on the annular electrostatic chuck, or may be the annular insulating member, or may be disposed on both the substrate support 51 and the annular insulating member. At least one RF/DC electrode coupled to an RF power supply 31 and/or a DC power supply 32 described later may be disposed in the ceramic member 51a. In this case, at least one RF/DC electrode functions as a lower electrode. In a case where a bias RF signal and/or a DC signal described later are supplied to at least one RF/DC electrode, the RF/DC electrode is also called a bias electrode. The conductive member of the base 50 and at least one RF/DC electrode may each function as a lower electrode. Further, the electrostatic electrode 51b may function as a lower electrode. Accordingly, the substrate support assembly 11 includes at least one lower electrode.

The ring assembly 112 includes one or more annular members. In one embodiment, one or more annular members include one or more edge rings and at least one cover ring. The edge ring is made of a conductive or insulating material, whereas the cover ring is made of an insulating material.

The showerhead 13 is configured to introduce at least one process gas from the gas supply 20 into the plasma processing space 10s. The showerhead 13 includes at least one gas supply port 13a, at least one gas diffusion space 13b, and a plurality of gas introduction ports 13c. The process gas supplied to the gas supply port 13a passes through the gas diffusion space 13b and is then introduced into the plasma processing space 10s from the plurality of gas introduction ports 13c. Further, the showerhead 13 includes at least one upper electrode. The gas introducer may include one or more side gas injectors (SGI) provided at one or more openings formed in the side wall 10a, in addition to the showerhead 13.

The gas supply 20 may include at least one gas source 21 and at least one flow rate controller 22. In one embodiment, the gas supply 20 is configured to supply at least one process gas from the corresponding gas source 21 through the corresponding flow rate controller 22 into the showerhead 13. Each flow rate controller 22 may be, for example, a mass flow controller or a pressure-controlled flow rate controller. Further, the gas supply 20 may include at least one flow rate modulation device that can modulate or pulse the flow rate of at least one process gas.

The power supply 30 includes the RF power supply 31 coupled to the plasma processing chamber 10 through at least one impedance matching circuit. The RF power supply 31 is configured to supply at least one RF signal (RF power) to at least one lower electrode and/or at least one upper electrode. As a result, a plasma is formed from at least one process gas supplied into the plasma processing space 10s. Therefore, the RF power supply 31 can function as at least part of the plasma generator 12. Further, by supplying a bias RF signal to at least one lower electrode, a bias potential is generated on the substrate W, and an ion component in the formed plasma can be attracted to the substrate W.

In one embodiment, the RF power supply 31 includes a first RF generator 31a and a second RF generator 31b. The first RF generator 31a is coupled to at least one lower electrode and/or at least one upper electrode through at least one impedance matching circuit, and is configured to generate a source RF signal (source RF power) for generating the plasma. In one embodiment, the source RF signal has a frequency in a range of 10 MHz to 150 MHz. In one embodiment, the first RF generator 31a may be configured to generate a plurality of source RF signals having different frequencies. The one or more generated source RF signals are supplied to at least one lower electrode and/or at least one upper electrode.

The second RF generator 31b is coupled to at least one lower electrode through at least one impedance matching circuit, and is configured to generate a bias RF signal (bias RF power). The frequency of the bias RF signal is the same as or different from the frequency of the source RF signal. In one embodiment, the bias RF signal has a frequency less than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The one or more generated bias RF signals are supplied to at least one lower electrode. Further, in various embodiments, at least one of the source RF signal and the bias RF signal may be pulsed.

The power supply 30 may also include the DC power supply 32 coupled to the plasma processing chamber 10. The DC power supply 32 includes a first DC generator 32a and a second DC generator 32b. In one embodiment, the first DC generator 32a is connected to at least one lower electrode, and is configured to generate a first DC signal. The generated first DC signal is applied to at least one lower electrode. In one embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform that is rectangular, trapezoidal, triangular, or a combination thereof. In one embodiment, a waveform generator for generating the sequence of voltage pulses from the DC signal is disposed between the first DC generator 32a and at least one lower electrode. Therefore, the first DC generator 32a and the waveform generator function as a voltage pulse generator. In a case where the second DC generator 32b and the waveform generator function as a voltage pulse generator, the voltage pulse generator is connected to at least one upper electrode. The voltage pulse may have positive polarity, or may be negative polarity. The sequence of voltage pulses may also include one or more positive-polarity voltage pulses and one or more negative-polarity voltage pulses within one cycle. The first and second DC generators 32a and 32b may be disposed in addition to the RF power supply 31, or the first DC generator 32a may be disposed instead of the second RF generator 31b.

The exhaust system 40 may be connected to, for example, a gas exhaust port 10e provided in the bottom portion of the plasma processing chamber 10. The exhaust system 40 may include a pressure adjustment valve and a vacuum pump. The pressure adjustment valve adjusts the pressure in the plasma processing space 10s. The vacuum pump may be a turbo-molecular pump, a dry pump, or a combination thereof.

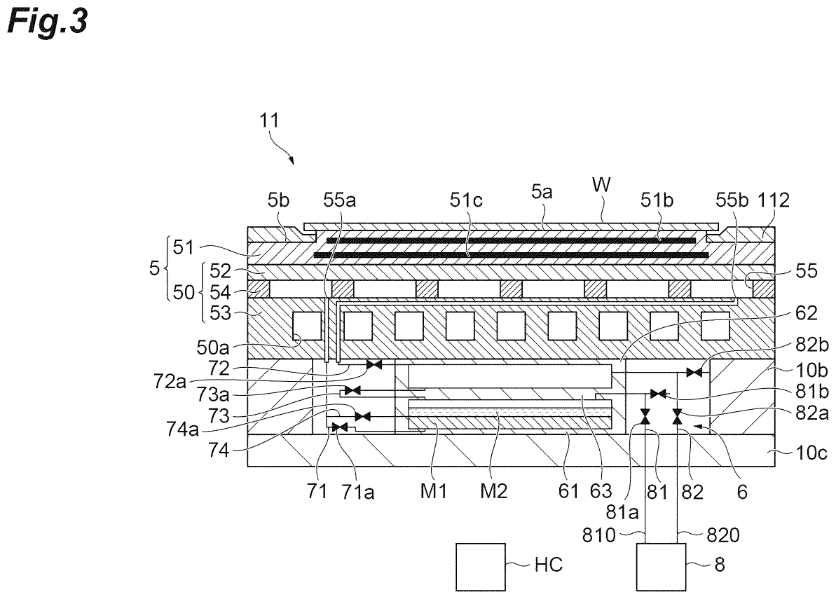

FIG. 3 is a diagram schematically showing the substrate support assembly according to one exemplary embodiment. As described above, the substrate support assembly 11 includes the main body 5. The main body 5 includes the base 50 and the substrate support 51 on the base 50. The substrate support 51 is disposed on the base 50. In one embodiment, the base 50 may be supported on a base member 10c via an insulating member 10b. In the example shown in FIG. 3, the main body 5 is supported by the insulating member 10b in the chamber 10. The insulating member 10b is disposed on the base member 10c. The base member 10c may constitute a bottom wall of the chamber 10.

In one embodiment, the substrate support assembly 11 may further include at least one heater 51c. The heater 51c is disposed in the substrate support 51. The heater 51c is disposed, for example, in a ceramic member 51a of the substrate support 51. The heater 51c is positioned below an electrostatic electrode 51b. The heater 51c generates heat by receiving power supplied from a power supply (not shown) controlled by a heater controller HC. The substrate support assembly 11 may include a temperature control module configured to adjust at least one of the substrate support 51, the ring assembly 112, and the substrate W to a target temperature. In addition, the substrate support assembly 11 may include a heat transfer gas supply configured to supply a heat transfer gas to a gap between a back surface of the substrate W and the central region 5a.

The base 50 includes a flow path 55 and a flow path 50a. In one embodiment, the flow path 55 is a flow path for at least one heat transfer medium, and the flow path 50a is a flow path for another heat transfer medium different from at least one heat transfer medium. The flow path 50a and the flow path 55 may be provided in the base 50. The flow path 50a and the flow path 55 may be independent of each other.

In one embodiment, at least one heat transfer medium may be a plurality of heat transfer media. The plurality of heat transfer media include a first heat transfer medium M1 (heat transfer medium) and a second heat transfer medium M2. The first heat transfer medium M1 has a first specific gravity. The second heat transfer medium M2 has a second specific gravity. The second specific gravity is smaller than the first specific gravity. The first heat transfer medium M1 has a first thermal conductivity. The second heat transfer medium M2 has a second thermal conductivity. The first thermal conductivity may be greater than the second thermal conductivity.

In one embodiment, the first heat transfer medium M1 may be a liquid metal. The liquid metal may be a metal or a eutectic alloy having a melting point of −10° C. or lower and a thermal conductivity of 5 W/mK or more at normal pressure (atmospheric pressure). The melting point of the liquid metal at normal pressure (atmospheric pressure) may be −15° C. or lower. The liquid metal is, for example, a Ga—In—Sn alloy. In the Ga—In—Sn alloy, a concentration of Ga may be 62% by mass, a concentration of In may be 25% by mass, and a concentration of Sn may be 13% by mass. The Ga—In—Sn alloy may be, for example, Galinstan (registered trademark). In one embodiment, the first heat transfer medium M1 may be a silicone oil, an anhydrous alcohol, ethylene glycol, or a fluorine-based refrigerant liquid. In one example, the first heat transfer medium M1 may be water.

In one embodiment, the second heat transfer medium M2 may be another liquid different from the liquid metal. The other liquid may be a liquid that does not chemically react with the liquid metal and does not contain moisture. Further, the other liquid may have a melting point lower than the melting point of the liquid metal. The other liquid is, for example, a silicone oil, an anhydrous alcohol, ethylene glycol, or a fluorine-based refrigerant liquid. In one example, the second heat transfer medium M2 may be water. The first heat transfer medium M1 and the second heat transfer medium M2 may be liquids that are incompatible with each other.

In one embodiment, the base 50 may include a first base 52, a second base 53, and a support member 54. The first base 52 supports the substrate support 51 disposed thereon. The second base 53 is disposed below the first base 52 and includes the flow path 50a inside. The support member 54 is interposed between the first base 52 and the second base 53 to support the first base 52. The support member 54 defines the flow path 55 between the first base 52 and the second base 53. In one example, the flow path 55 extends between the flow path 50a and the substrate support 51.

In one embodiment, the thermal conductivity of the material of the support member 54 may be lower than the thermal conductivity of the material of the base 50. The thermal conductivity of the material of the support member 54 may be 1 W/mK or less. The support member 54 includes, for example, at least one material selected from the group consisting of a resin material, ceramic, and a composite material. The support member 54 may include a fluororesin. The support member 54 may include at least one material selected from the group consisting of polytetrafluoroethylene, polyether ether ketone, and porous ceramic. The support member 54 may include a composite material. The composite material is a material made by combining two or more different materials. For example, the composite material is a material made by combining two or more materials selected from the group consisting of resin, metal, glass, and carbon.

The other heat transfer medium different from at least one heat transfer medium may be, for example, a refrigerant such as brine or gas. The substrate support assembly 11 may further include a chiller unit. The chiller unit may be connected to the flow path 50a to supply the other heat transfer medium to the flow path 50a.

The substrate support assembly 11 includes a heat transfer medium supply 6. The heat transfer medium supply 6 is connected to the flow path 55 and is configured to supply the heat transfer medium selected from among the plurality of heat transfer media described above to the flow path 55. The above-described temperature control module may include the heat transfer medium supply 6, the heater 51c, the heater controller HC, the flow path 55, the flow path 50a, the chiller unit, or a combination thereof.

In one embodiment, the heat transfer medium supply 6 may be disposed between the base member 10c and the base 50. The heat transfer medium supply 6 may be disposed inside the chamber 10. However, the heat transfer medium supply 6 may be disposed outside the chamber 10. The heat transfer medium supply 6 is insulated from the chamber 10.

The heat transfer medium supply 6 includes at least one first pipe 71, a first container 61, at least one second pipe 72, a second container 62, at least one third pipe 73, a valve 73a (third valve), a first gas supply 81, and a second gas supply 82. In one embodiment, the heat transfer medium supply 6 may further include a valve 71a (first valve), a valve 72a (second valve), at least one fourth pipe 74, and a valve 74a (fourth valve).

At least one first pipe 71 is connected between the first end 55a of the flow path 55 and the first container 61. In one embodiment, the valve 71a is connected between the first end 55a and the first container 61 via at least one first pipe 71. In the example shown in FIG. 3, the heat transfer medium supply 6 includes a plurality of first pipes 71. One of the plurality of first pipes 71 connects the first end 55a and the valve 71a to each other, and another one of the plurality of first pipes 71 connects the valve 71a and the first container 61 to each other. The first container 61 may be provided below the second container 62 as described later. A position at which the other one of the plurality of first pipes 71 is connected to the first container 61 may be, for example, a bottom portion of the first container 61.

At least one second pipe 72 is connected between the second end 55b of the flow path 55 and the second container 62. The second end 55b is an end of the flow path 55 on a side opposite to the first end 55a. In one embodiment, the valve 72a is connected between the second end 55b and the second container 62 via at least one second pipe 72. In the example shown in FIG. 3, the heat transfer medium supply 6 includes a plurality of second pipes 72. One of the plurality of second pipes 72 connects the second end 55b and the valve 72a to each other, and another one of the plurality of second pipes 72 connects the valve 72a and the second container 62 to each other. A position at which the other one of the plurality of second pipes 72 is connected to the second container 62 may be, for example, a ceiling (or an upper wall) of the second container 62.

At least one third pipe 73 is connected between the first container 61 and the second container 62. The valve 73a is connected between the first container 61 and the second container 62 via at least one third pipe 73. In the example shown in FIG. 3, the heat transfer medium supply 6 includes a plurality of third pipes 73. One of the plurality of third pipes 73 connects the first container 61 and the valve 73a to each other, and another one of the plurality of third pipes 73 connects the valve 73a and the second container 62 to each other. A position at which one of the plurality of third pipes 73 is connected to the first container 61 is a position higher than a position at which the other one of the plurality of first pipes 71 is connected to the first container 61, and may be, for example, a ceiling (or an upper wall) of the first container 61. In addition, a position at which another one of the plurality of third pipes 73 is connected to the second container 62 is a position lower than a position at which the other one of the plurality of second pipes 72 is connected to the second container 62, and may be, for example, a bottom portion of the second container 62.

At least one fourth pipe 74 is connected between the first end 55a and the first container 61. At least one fourth pipe 74 may be provided in parallel with at least one first pipe 71, or may merge with at least one first pipe 71. A position at which at least one fourth pipe 74 is connected to the first container 61 is positioned above a position at which at least one first pipe 71 is connected to the first container 61. In addition, a position at which at least one fourth pipe 74 is connected to the first container 61 is positioned below a position at which at least one third pipe 73 is connected to the first container 61. The valve 74a is connected between the first end 55a and the first container 61 via at least one fourth pipe 74. In the example shown in FIG. 3, the heat transfer medium supply 6 includes a plurality of fourth pipes 74. One of the plurality of fourth pipes 74 connects the first end 55a and the valve 74a to each other, and another one of the plurality of fourth pipes 74 connects the valve 74a and the first container 61 to each other. One of the plurality of fourth pipes 74 may merge with at least one first pipe 71 between the first end 55a and the valve 74a.

The first container 61 is configured to store the first heat transfer medium M1 therein. In one embodiment, the first container 61 may be configured to further store the second heat transfer medium M2 therein. The second container 62 may be configured to store the second heat transfer medium M2 therein.

In one embodiment, the first container 61 is disposed below the second container 62, and the second container 62 is disposed above the first container 61. In the example shown in FIG. 3, the first container 61 and the second container 62 are separated by a single partition wall 63. In one embodiment, at least one of the inner surface of the first container 61, the inner surfaces of the plurality of first pipes 71, and the inner surface of the flow path 55 may include resin or ceramic. In this case, the embrittlement of each inner surface due to the liquid metal is inhibited. In one embodiment, at least one of the inner surface of the second container 62, the inner surfaces of the plurality of second pipes 72, and the inner surfaces of at least one third pipe 73 may include resin or ceramic. In this case, the embrittlement of each inner surface due to the liquid metal is inhibited.

Since the first container 61 is disposed below the second container 62, when the valve 73a is opened, the first heat transfer medium M1 and the second heat transfer medium M2 stored in the second container 62 are recovered in the first container 61 via at least one third pipe 73.

The first gas supply 81 is connected to the first container 61. In one example, the first gas supply 81 includes at least one first gas pipe 810 connected between the first container 61 and the gas source 8. The gas source 8 may be a gas cylinder, a compressor, or a gas booster. The first gas supply 81 is configured to supply the first gas to the first container 61 in order to supply the first heat transfer medium M1 in the first container 61 to the flow path 55 via at least one first pipe 71. The first gas is, for example, nitrogen or a noble gas.

The first gas supply 81 may include a valve 81a (fifth valve). The valve 81a is connected between the first container 61 and the gas source 8 via at least one first gas pipe 810. In the example shown in FIG. 3, the first gas supply 81 is a plurality of first gas pipes 810 connected between the first container 61 and the gas source 8. One of the plurality of first gas pipes 810 connects the gas source 8 and the valve 81a to each other, and another one of the plurality of first gas pipes 810 connects the valve 81a and the first container 61 to each other. A position at which the first gas supply 81 is connected to the first container 61 may be, for example, a ceiling (or an upper wall) of the first container 61.

In one embodiment, the substrate support assembly 11 may include an exhauster 81b (first exhauster). The exhauster 81b is configured to exhaust the gas in the first container 61. The exhauster 81b may exhaust the gas inside the first container 61 to the outside of the chamber 10, or may exhaust the gas inside the first container 61 into the chamber 10. In one example, the exhauster 81b includes a first leak valve connected to the first container 61. The exhauster 81b may include a vacuum pump connected to the first leak valve. In the example shown in FIG. 3, the first leak valve is connected to an end of the first gas pipe 810, which is connected to the first container 61, among the plurality of first gas pipes 810.

The second gas supply 82 is connected to the second container 62. In one example, the second gas supply 82 includes at least one second gas pipe 820 connected between the second container 62 and the gas source 8. The second gas supply 82 is configured to supply the second gas to the second container 62. The gas is, for example, nitrogen or a noble gas. The second gas may be the same as or different from the first gas.

The second gas supply 82 may include a valve 82a (sixth valve). The valve 82a is connected between the second container 62 and the gas source 8 via at least one second gas pipe 820. In the example shown in FIG. 3, the second gas supply 82 is a plurality of second gas pipes 820 connected between the second container 62 and the gas source 8. One of the plurality of second gas pipes 820 connects the gas source 8 and the valve 82a to each other, and another one of the plurality of second gas pipes 820 connects the valve 82a and the second container 62 to each other. A position at which the second gas supply 82 is connected to the second container 62 may be, for example, a ceiling (or an upper wall) of the second container 62.

In one embodiment, the substrate support assembly 11 may include an exhauster 82b (second exhauster). The exhauster 82b is configured to exhaust the gas in the second container 62. The exhauster 82b may exhaust the gas inside the second container 62 to the outside of the chamber 10, or may exhaust the gas inside the second container 62 into the chamber 10. In one example, the exhauster 82b includes a second leak valve connected to the second container 62. The exhauster 82b may include a vacuum pump connected to the second leak valve. In the example shown in FIG. 3, the second leak valve is connected to an end of the second gas pipe 820, which is connected to the second container 62, among the plurality of second gas pipes 820.

In a case where there is no first heat transfer medium M1 in the flow path 55, the thermal resistance between the base 50 (second base 53) and the substrate support 51 is large. Therefore, the temperature of the substrate support 51 can be adjusted to a temperature apart from the temperature of the base 50. As a result, the temperature of the substrate W on the substrate support 51 is adjusted in a relatively high temperature range. In a case where there is the first heat transfer medium M1 in the flow path 55, the thermal resistance between the base 50 and the substrate support 51 is small. Therefore, the temperature of the substrate support 51 can be adjusted to a temperature close to the temperature of the base 50. As a result, the temperature of the substrate W on the substrate support 51 is adjusted in a relatively low temperature range. In the substrate support assembly 11, the first heat transfer medium M1 is supplied to the flow path 55, and the first heat transfer medium M1 is further collected from the flow path 55, so that the substrate temperature controllability of the substrate support assembly 11 is excellent.

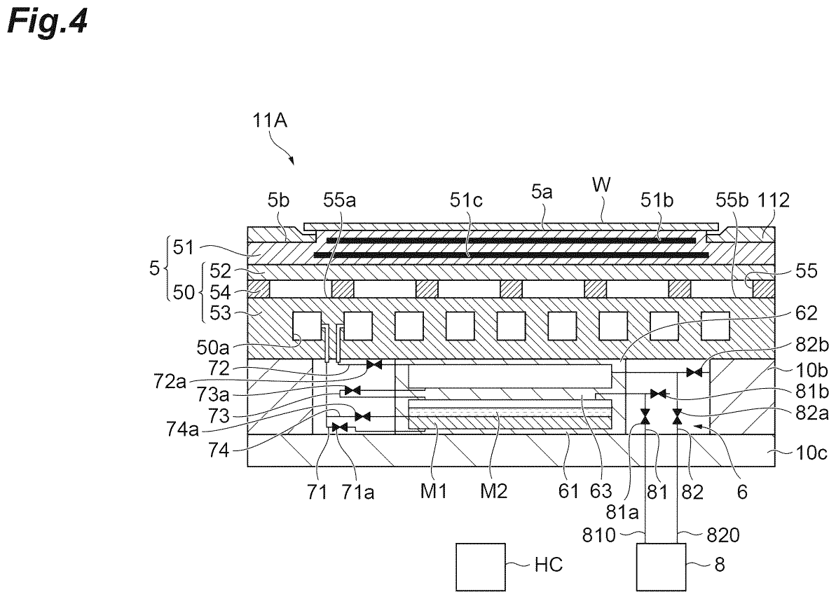

Hereinafter, a substrate support assembly according to another exemplary embodiment will be described with reference to FIG. 4. FIG. 4 is a cross-sectional view of the substrate support assembly according to another exemplary embodiment. A substrate support assembly 11A shown in FIG. 4 may be adopted instead of the substrate support assembly 11 in the plasma processing apparatus 1. Hereinafter, the substrate support assembly 11A will be described in terms of differences from the substrate support assembly 11.

In the substrate support assembly 11A, the flow path 50a is a flow path for at least one heat transfer medium. The flow path 55 may be a flow path for the other heat transfer medium different from at least one heat transfer medium. At least one first pipe 71 is connected between a first end of the flow path 50a and the first container 61. At least one second pipe 72 is connected between a second end of the flow path 50a and the second container 62. The second end of the flow path 50a is an end on a side opposite to the first end of the flow path 50a. The substrate support assembly 11A may further include a chiller unit. The chiller unit may be connected to the flow path 55 to supply the other heat transfer medium to the flow path 55. For example, the chiller unit is connected to each of the first end 55a and the second end 55b.

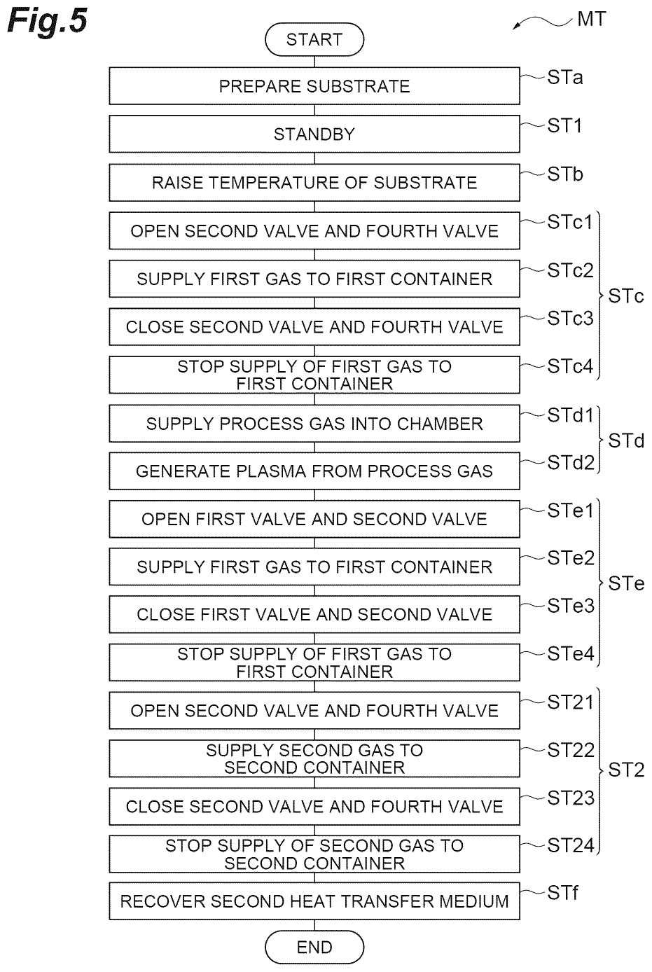

Hereinafter, a substrate processing method according to one exemplary embodiment will be described with reference to FIG. 5. FIG. 5 is a flowchart of the substrate processing method according to one exemplary embodiment. The substrate processing method (hereinafter, referred to as a “method MT”) shown in FIG. 5 may be executed by the plasma processing system shown in FIG. 1. Hereinafter, a case where the controller 2 or an operator controls each portion of the plasma processing apparatus 1 including the substrate support assembly 11 or the substrate support assembly 11A to execute the substrate processing method with respect to the substrate W will be described as an example.

The method MT includes step STa, step STb, step STc, step STd, step STe, and step STf. The method MT may include step ST1 and step ST2.

First, step STa is performed. In step STa, the substrate W is prepared on the substrate support 51 in the chamber 10 of the plasma processing apparatus 1. The steps of the method MT performed after step STa are performed in a state where the substrate W is placed on the substrate support 51.

In one embodiment, step ST1 may be performed after step STa and before step STb. In step ST1, the plasma processing apparatus 1 is in a standby state. In step ST1, the power may be supplied to the heater 51c from the power supply controlled by the heater controller HC in a state where the valves 71a, 72a, 73a, and 74a may be closed and at least the first heat transfer medium M1 and the second heat transfer medium M2 are not supplied to the flow path 55. The power supplied to the heater 51c in step ST1 may be smaller than the power supplied to the heater 51c in step STb described later. In one example, the first power may be supplied to the heater 51c. The temperature of the substrate W on the substrate support 51 may be a first temperature due to the heat generation of the heater 51c.

After step STa, step STb is performed. Step STb may be performed after step ST1. In step STb, the temperature of the substrate W prepared on the substrate support 51 is increased. Step STb includes a step of supplying the power to the heater 51c from the power supply controlled by the heater controller HC in a state where the valves 71a, 72a, 73a, and 74a are closed and at least the first heat transfer medium M1 and the second heat transfer medium M2 are not supplied to the flow path 55. The power supplied to the heater 51c in step STb may be greater than the power supplied to the heater 51c in step ST1. In one example, the second power may be supplied to the heater 51c. The second power is greater than the first power. The substrate W on the substrate support 51 may be heated to a second temperature as a target due to the heat generation of the heater 51c. The second temperature is higher than the first temperature.

In step STb, since at least the first heat transfer medium M1 and the second heat transfer medium M2 are not present in the flow path 55, the thermal resistance between the base 50 (second base 53) and the substrate support 51 is large. Therefore, the temperature of the substrate support 51 can be adjusted to a temperature apart from the temperature of the base 50. As a result, the temperature of the substrate W on the substrate support 51 is adjusted in a relatively high temperature range.

After step STb, step STc is performed. In step STc, the temperature of the substrate W disposed on the substrate support 51 is adjusted. The temperature to which the temperature of the substrate W is adjusted is a temperature for the substrate processing on the substrate W. Step STc includes step STc1, step STc2, step STc3, and step STc4. Step STc includes a step of supplying power smaller than the power in step STb from the power supply controlled by the heater controller HC to the heater 51c. In one example, the temperature of the substrate W on the substrate support 51 may be maintained at the second temperature by the heat generation of the heater 51c.

In step STc1, step STc2, step STc3, and step STc4, step STc1 is performed first. In step STc1, the valve 72a and the valve 74a are opened. After step STc1, step STc2 is performed. In step STc2, the exhaust of the gas in the second container 62 by the exhauster 82b and the supply of the first gas to the first container 61 by the first gas supply 81 are performed. In step STc2, for example, the valve 81a may be opened in a state where the second leak valve is opened. The gas in the second container is exhausted and the pressure in the second container is decreased, and the gas is supplied into the first container 61 and the pressure in the first container 61 is increased, so that the second heat transfer medium M2 is supplied to the flow path 55 via at least one fourth pipe 74. After step STc2, step STc3 is performed. In step STc3, the valve 72a and the valve 74a are closed. In step STc3, the second heat transfer medium M2 is held in the flow path 55. After step STc2, step STc4 is performed. Step STc4 may be performed after step STc3 or may be performed before step STc3. In step STc4, the exhaust by the exhauster 82b and the supply of the first gas to the first container 61 by the first gas supply 81 are stopped.

After step STc, step STd is performed. In step STd, the substrate processing is performed on the substrate W disposed on the substrate support 51. In one example, the plasma processing may be performed in step STd. Step STd includes step STd1 and step STd2. Step STd includes a step of supplying power smaller than the power in step STb to the heater 51c from the power supply controlled by the heater controller HC. In one example, the temperature of the substrate W on the substrate support 51 may be maintained at the second temperature by the heat generation of the heater 51c.

In step STd1 and step STd2, step STd1 is performed first. In step STd1, the process gas is supplied into the chamber 10 from the gas introducer (for example, the showerhead 13). After step STd1, step STd2 is performed. In step STd2, the plasma generator 12 generates the plasma from the process gas in the chamber 10.

After step STd, step STe is performed. In step STe, the first heat transfer medium M1 is supplied to the flow path 55. In step STe, the temperature of the substrate W disposed on the substrate support 51 is lowered. Step STe includes step STe1, step STe2, step STe3, and step STe4 in order to supply the first heat transfer medium M1 to the flow path 55.

In step STe1, step STe2, step STe3, and step STe4, step STe1 is performed first. In step STe1, the valve 71a and the valve 72a are opened. After step STe1, step STe2 is performed. In step STe2, the exhaust of the gas in the second container 62 by the exhauster 82b and the supply of the first gas to the first container 61 by the first gas supply 81 are performed. For example, in step STe2, the valve 81a may be opened in a state where the second leak valve is opened. The gas in the second container is exhausted and the pressure in the second container is decreased, and the gas is supplied into the first container 61 and the pressure in the first container 61 is increased, so that the first heat transfer medium M1 is supplied to the flow path 55 via at least one first pipe 71. By supplying the first heat transfer medium M1 to the flow path 55, the second heat transfer medium M2 in the flow path 55 can be recovered into the second container 62. After step STe2, step STe3 is performed. In step STe3, the valve 71a and the valve 72a are closed. In step STe3, the first heat transfer medium M1 is held in the flow path 55. After step STe2, step STe4 is performed. Step STe4 may be performed after step STe3 or may be performed before step STe3. In step STe4, the exhaust by the exhauster 82b and the supply of the first gas to the first container 61 by the first gas supply 81 are stopped.

In step STe, since the first heat transfer medium M1 is present in the flow path 55, the thermal resistance between the base 50 and the substrate support 51 is small. Therefore, the temperature of the substrate support 51 can be adjusted to a temperature close to the temperature of the base 50. As a result, the temperature of the substrate W on the substrate support 51 is adjusted in a relatively low temperature range.

In one embodiment, step ST2 may be performed after step STe and before step STf. Step ST2 includes step ST21, step ST22, step ST23, and step ST24. In step ST21, step ST22, step ST23, and step ST24, step ST21 is first performed. In step ST21, the valve 72a and the valve 74a are opened. In step ST21, the valve 71a may be further opened. After step ST21, step ST22 is performed. In step ST22, the exhaust of the gas in the first container 61 by the exhauster 81b and the supply of the second gas to the second container 62 by the second gas supply 82 are performed. In step ST22, for example, the valve 82a may be opened in a state where the first leak valve is opened. The gas in the first container is exhausted and the pressure in the first container is decreased, and the gas is supplied into the second container 62 and the pressure in the second container 62 is increased, so that the gas is supplied to the flow path 55 via at least one second pipe 72. Since the gas is supplied to the flow path 55, the first heat transfer medium M1 in the flow path 55 may be recovered in the first container 61 via at least one fourth pipe 74. The first heat transfer medium M1 in the flow path 55 may be recovered in the first container 61 via at least one first pipe 71. After step ST22, step ST23 is performed. In step ST23, the valve 74a and the valve 72a are closed. After step ST22, step ST24 is performed. Step ST24 may be performed after step ST23 or may be performed before step ST23. In step ST24, the exhaust by the exhauster 81b and the supply of the second gas to the second container 62 by the second gas supply 82 are stopped.

After step STe, step STf is performed. Step STf may be performed after step ST2. In step STf, at least the second heat transfer medium M2 is recovered from the second container 62 to the first container 61. In step STf, the first heat transfer medium M1 and the second heat transfer medium M2 may be recovered from the second container 62 to the first container 61. Step STf includes a step of opening the valve 73a in a state where the valve 71a, the valve 72a, and the valve 74a are closed. The second heat transfer medium M2 is recovered from the second container 62 to the first container 61 via at least one third pipe 73. In step STf, the exhauster 81b may exhaust the gas in the first container. In step STf, the second gas supply 82 may supply the second gas to the second container 62.

Although various exemplary embodiments have been described above, various additions, omissions, substitutions, and modifications may be made without being limited to the exemplary embodiments described above. Further, other embodiments can be formed by combining the elements in different embodiments.

The flow path 55 may include a plurality of flow paths independent of each other. In one example, the flow path 55 may include a first flow path positioned below the central region 5a (substrate support surface) and a second flow path positioned below the annular region 5b (ring support surface).

A plurality of gas sources 8 may be provided. In one example, the gas source 8 includes a first gas source and a second gas source different from the first gas source. For example, the first gas supply 81 may include at least one first gas pipe connected between the first container 61 and the first gas source, and the second gas supply 82 may include at least one second gas pipe connected between the second container 62 and the second gas source.

In the method MT, all of steps STa to STf need not be executed. In one example, in the method MT, some of steps STa to STf may be skipped.

In one embodiment, the method MT may include step STn (not shown) of supplying both the first heat transfer medium M1 and the second heat transfer medium M2 to the flow path 55. In the method MT, step STn may be executed instead of step STc or step STe, or may be executed before or after step STc or step STe. Step STn includes step STn1, step STn2, and step STn3.

In step STn1, the valve 71a, the valve 72a, and the valve 74a are opened. After step STn1, step STn2 is performed. In step STn2, the exhaust of the gas in the second container 62 by the exhauster 82b and the supply of the first gas to the first container 61 by the first gas supply 81 are performed. In step STn2, for example, the valve 81a may be opened in a state where the second leak valve is opened. The gas in the second container 62 is exhausted, and the pressure in the second container 62 is decreased, whereas the gas is supplied to the first container 61, and the pressure in the first container 61 is increased. As the pressure in the first container 61 is increased, the first heat transfer medium M1 is supplied to the flow path 55 via at least one first pipe 71, and the second heat transfer medium M2 is supplied to the flow path 55 via at least one fourth pipe 74. After step STn2, step STn3 is performed. In step STn3, the valve 71a, the valve 72a, and the valve 74a are closed. In step STn3, the first heat transfer medium M1 and the second heat transfer medium M2 are held in the flow path 55.

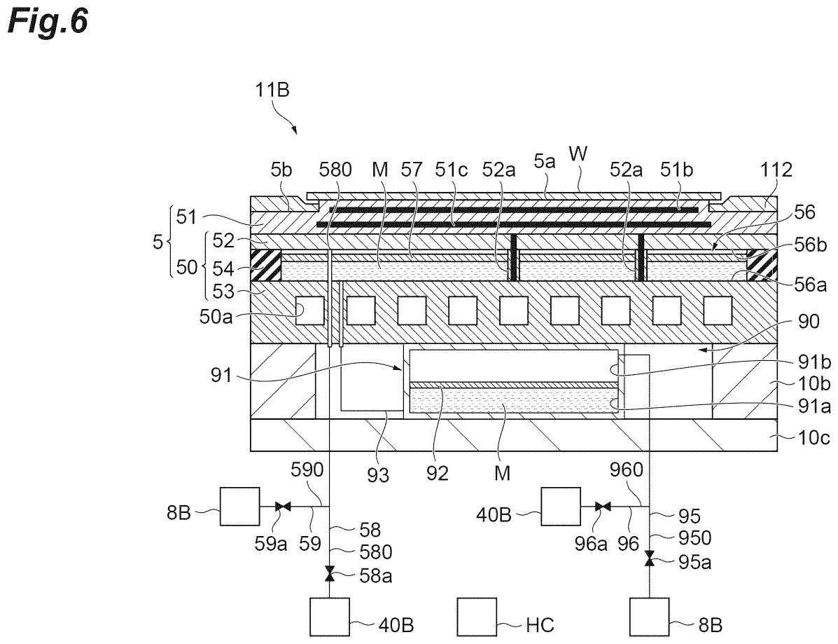

Hereinafter, a substrate support assembly according to still another exemplary embodiment will be described with reference to FIG. 6. FIG. 6 is a cross-sectional view of the substrate support assembly according to still another exemplary embodiment. A substrate support assembly 11B shown in FIG. 6 may be adopted in the plasma processing apparatus 1 instead of the substrate support assembly 11. Hereinafter, the substrate support assembly 11B will be described in terms of differences from the substrate support assembly 11. The substrate support assembly 11B includes a base 50, a movable plate 57, a substrate support 51 on the base 50, a heat transfer medium supply 90, and a first exhauster 58 (exhauster).

In the substrate support assembly 11B, the base 50 includes a tank 56 instead of the flow path 55. The tank 56 may be provided in the base 50. In one embodiment, the support member 54 of the base 50 defines the tank 56 between the first base 52 and the second base 53. In one example, the tank 56 is formed between the flow path 50a and the substrate support 51. The tank 56 may be a tank for a plurality of heat transfer media. The plurality of heat transfer media include a first heat transfer medium M1 and a second heat transfer medium M2. In the example shown in FIG. 6, the tank 56 is a tank for a single heat transfer medium M. The heat transfer medium M includes the first heat transfer medium M1 or the second heat transfer medium M2. In one embodiment, the heat transfer medium M may be the above-described liquid metal.

The movable plate 57 is configured to separate the inner portion of the tank 56 into a first space 56a and a second space 56b, and configured to move between the first space 56a and the second space 56b along a direction in which the first space 56a and the second space 56b are arranged. The movable plate 57 can slide along an inner surface of the tank 56. In one embodiment, the first space 56a and the second space 56b are arranged in an up-down direction. In the example shown in FIG. 6, the first space 56a is positioned below the second space 56b. The movable plate 57 may extend to face the support member 54 between the first base 52 and the second base 53. In one embodiment, the movable plate 57 moves in the up-down direction. In one example, the inner surface of the tank 56 and the movable plate 57 includes ceramic. Further, the movable plate 57 may be a metal covered with resin or ceramic.

The first exhauster 58 is configured to exhaust the gas in the second space 56b. In one example, the first exhauster 58 includes at least one gas pipe 580 and a valve 58a connected between the second space 56b and the vacuum pump 40B. The first exhauster 58 may exhaust the gas inside the second space 56b to the outside of the chamber 10, or may exhaust the gas inside the second space 56b into the chamber 10. In the example shown in FIG. 6, the valve 58a is connected to an end of the gas pipe 580 connected to the second space 56b among the plurality of gas pipes 580. The first exhauster 58 may exhaust the gas in the second space 56b to the atmosphere without using the vacuum pump 40B.

The heat transfer medium supply 90 is connected to the first space 56a and is configured to supply at least one heat transfer medium to the tank 56. The above-described temperature control module may include the heat transfer medium supply 90, the heater 51c, the heater controller HC, the tank 56, the movable plate 57, the flow path 50a, the chiller unit, or a combination thereof.

In one embodiment, the heat transfer medium supply 90 may be disposed between the base member 10c and the base 50. The heat transfer medium supply 90 may be disposed inside the chamber 10. However, the heat transfer medium supply 90 may be disposed outside the chamber 10. The heat transfer medium supply 90 is insulated from the chamber 10.

The heat transfer medium supply 90 includes a cylinder 91, a piston 92, and a pipe 93. The cylinder 91 and the piston 92 may be disposed inside the chamber 10. The cylinder 91 and the piston 92 may be disposed between the base member 10c and the base 50. The piston 92 is configured to separate the inner portion of the cylinder 91 into a third space 91a and a fourth space 91b, and configured to move between the third space 91a and the fourth space 91b along a direction in which the third space 91a and the fourth space 91b are arranged. The piston 92 slides along an inner surface of the cylinder 91. In one embodiment, the third space 91a and the fourth space 91b are arranged in an up-down direction. In the example shown in FIG. 6, the third space 91a is positioned below the fourth space 91b. The piston 92 can move in the up-down direction between the third space 91a and the fourth space 91b. In one example, the cylinder 91 and the piston 92 includes ceramic. In addition, the piston 92 may be a metal covered with resin or ceramic.

The third space 91a is configured to store the heat transfer medium M. The pipe 93 is connected between the third space 91a and the first space 56a. The piston 92 is configured to move such that a volume of the third space 91a is decreased in order to supply the heat transfer medium M in the third space 91a to the first space 56a via the pipe 93. In the example shown in FIG. 6, the piston 92 moves downward such that the volume of the third space 91a is decreased. In one example, the substrate support assembly 11B may include a driver that moves the piston 92.

With the substrate support assembly 11B, the first space 56a in which the heat transfer medium M is stored and the second space 56b to which the gas is supplied in the tank 56 are separated by the movable plate 57. The third space 91a in which the heat transfer medium M is stored and the fourth space 91b to which the gas is introduced in the cylinder 91 are separated by the piston 92. Therefore, the substrate support assembly 11B can reduce the possibility that the heat transfer medium M flows out to a gas pipe 950 and/or a gas pipe 580 described later.

In one embodiment, the heat transfer medium supply 90 may include a first gas supply 95 (gas supply) connected to the fourth space 91b. In one example, the first gas supply 95 includes at least one gas pipe 950 connected between the fourth space 91b and a gas source 8B. The gas source 8B may be a gas cylinder, a compressor, or a gas booster. The first gas supply 95 is configured to supply the gas to the fourth space 91b in order to supply the heat transfer medium M in the third space 91a to the first space 56a via the pipe 93. The gas is, for example, nitrogen or a noble gas. The first gas supply 95 is configured to supply the gas to the fourth space 91b and move the piston 92 such that the volume of the third space 91a is decreased by increasing the volume of the fourth space 91b.

The first gas supply 95 may include a valve 95a. The valve 95a is connected between the fourth space 91b and the gas source 8B via at least one gas pipe 950. In the example shown in FIG. 6, the first gas supply 95 is a plurality of gas pipes 950 connected between the fourth space 91b and the gas source 8B. One of the plurality of gas pipes 950 connects the gas source 8B and the valve 95a to each other, and another one of the plurality of gas pipes 950 connects the valve 95a and the fourth space 91b to each other. A position at which the first gas supply 95 is connected to the fourth space 91b may be, for example, a ceiling (or an upper wall) of the fourth space 91b.

In one embodiment, the heat transfer medium supply 90 may include a second exhauster 96. The second exhauster 96 is configured to exhaust the gas in the fourth space 91b. In one example, the second exhauster 96 includes at least one gas pipe 960 connected between the fourth space 91b and the vacuum pump 40B and a valve 96a. The second exhauster 96 may exhaust the gas inside the fourth space 91b to the outside of the chamber 10, or may exhaust the gas inside the fourth space 91b into the chamber 10. In the example shown in FIG. 6, the gas pipe 960 and the valve 96a are connected to the gas pipe 950 connected to the fourth space 91b. The second exhauster 96 may exhaust the gas in the fourth space 91b to the atmosphere without using the vacuum pump 40B. The gas pipe 960 may be connected to the fourth space 91b without using the gas pipe 950.

In one embodiment, the piston 92 is configured to move to decrease the volume of the fourth space 91b in order to supply the heat transfer medium M in the first space 56a to the third space 91a via the pipe 93. In one embodiment, the second exhauster 96 is configured to move the piston 92 such that the gas is exhausted from the fourth space 91b, the volume of the fourth space 91b is decreased, and the volume of the third space 91a is increased in order to supply the heat transfer medium M in the first space 56a to the third space 91a via the pipe 93.

In one embodiment, the substrate support assembly 11B may include a second gas supply 59 connected to the second space 56b. The movable plate 57 may be configured to move such that the volume of the first space 56a is decreased in order to supply the heat transfer medium M in the first space 56a to the third space 91a via the pipe 93. In one example, the second gas supply 59 includes at least one gas pipe 590 connected between the second space 56b and the gas source 8B. The second gas supply 59 is configured to supply the gas to the second space 56b in order to supply the heat transfer medium M in the first space 56a to the third space 91a via the pipe 93. The second gas supply 59 is configured to move the movable plate 57 in order to supply the gas to the second space 56b and increase the volume of the second space 56b such that the volume of the first space 56a is decreased.

The second gas supply 59 may include a valve 59a. The valve 59a is connected between the second space 56b and the gas source 8B via at least one gas pipe 590. In the example shown in FIG. 6, the second gas supply 59 is a plurality of gas pipes 590 connected between the second space 56b and the gas source 8B. One of the plurality of gas pipes 590 connects the gas source 8B and the valve 59a to each other, and another one of the plurality of gas pipes 590 connects the valve 59a and the second space 56b to each other. A position at which the second gas supply 59 is connected to the second space 56b may be, for example, a ceiling (or an upper wall) of the second space 56b. The second gas supply 59 need not be connected to the gas source 8B. The valve 59a may be opened to the atmosphere via at least one gas pipe 590.

In one embodiment, the base 50 includes at least one conduit 52a. In the example shown in FIG. 6, at least one conduit 52a includes a plurality of conduits 52a. Each conduit 52a may be included in the first base 52. Each conduit 52a extends downward from a top surface of the tank 56 in the tank 56. Each conduit 52a has a tube shape providing a void inside. In one embodiment, a pipe for supplying a refrigerant such as brine or gas, an electric wire connected to the electrostatic electrode 51b, an electric wire for supplying an RF signal to the lower electrode, a pipe for supplying a heat transfer gas to a gap between the back surface of the substrate W and the central region 5a, or a lifter pin for raising and lowering the substrate W may be disposed in each of the plurality of conduits 52a. The movable plate 57 is provided with a plurality of through-holes into which the plurality of conduits 52a are inserted.

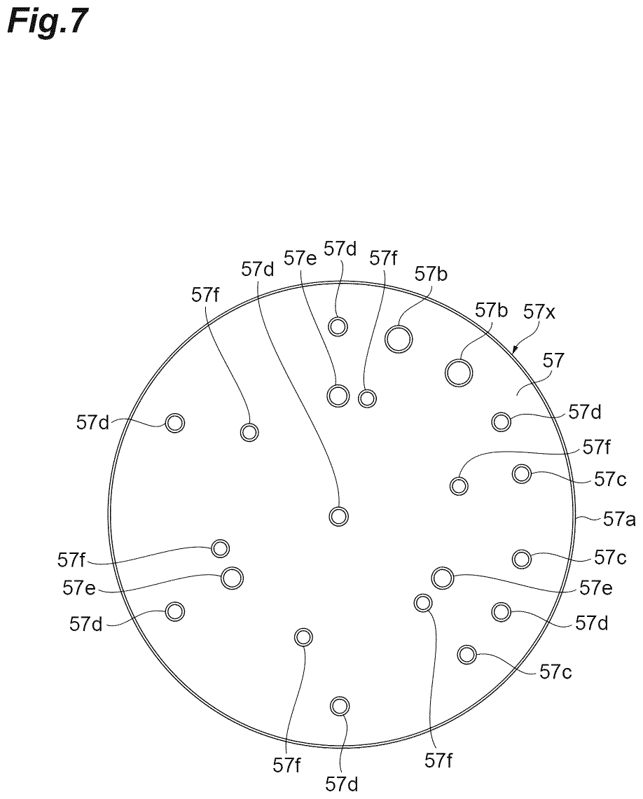

FIG. 7 is a plan view of the movable plate according to one exemplary embodiment. In one embodiment, the movable plate 57 includes a plurality of seal members 57x. Each of the plurality of seal members 57x may be an O-ring. The plurality of seal members 57x may include a seal member 57a disposed between a side surface of the movable plate 57 and the inner surface of the tank 56. The plurality of seal members 57x may include a plurality of seal members disposed between an inner surface that defines each of the plurality of through-holes of the movable plate 57 and a side surface of each of the plurality of conduits 52a.

The plurality of seal members 57x may include a plurality of seal members 57b, 57c, 57d, 57e, and 57f. The sizes of the plurality of seal members 57b, 57c, 57d, 57e, and 57f may be different from each other. The plurality of seal members 57b may be disposed adjacent to each other in a circumferential direction of the movable plate 57. The plurality of seal members 57d may be disposed at equal intervals in the circumferential direction of the movable plate 57. One of the plurality of seal members 57d may be disposed at the center of the movable plate 57.

In one example, the seal member 57b may be disposed between a side surface of the conduit 52a in which a pipe for supplying a refrigerant such as brine or gas is disposed and an inner surface that defines a corresponding through-hole of the movable plate 57. In one example, the seal member 57c may be disposed between a side surface of the conduit 52a in which an electric wire connected to the electrostatic electrode 51b is disposed and an inner surface that defines a corresponding through-hole of the movable plate 57. In one example, the seal member 57d may be disposed between a side surface of the conduit 52a in which an electric wire for supplying an RF signal to the lower electrode is disposed and an inner surface that defines a corresponding through-hole of the movable plate 57. In one example, the seal member 57e may be disposed between a side surface of the conduit 52a in which a lifter pin for lifting and lowering the substrate W is disposed and an inner surface that defines a corresponding through-hole of the movable plate 57. In one example, the seal member 57f may be disposed between a side surface of the conduit 52a in which a pipe for supplying a heat transfer gas to a gap between the back surface of the substrate W and the central region 5a is disposed and an inner surface that defines a corresponding through-hole of the movable plate 57.

In one embodiment, the gas pipe 580 may be connected to the second space 56b from below the tank 56. In this case, the gas pipe 580 connected to the second space 56b may be inserted into the corresponding through-hole of the movable plate 57 through the first space 56a and connected to the second space 56b. A seal member may be disposed between the inner surface that defines a corresponding through-hole of the movable plate 57 and a side surface of the gas pipe 580. The gas pipe 580 is connected to the second space 56b from below the tank 56 and the gas pipe 580 is not disposed above the tank 56, and thus a distance between the tank 56 and the substrate support 51 can be decreased.

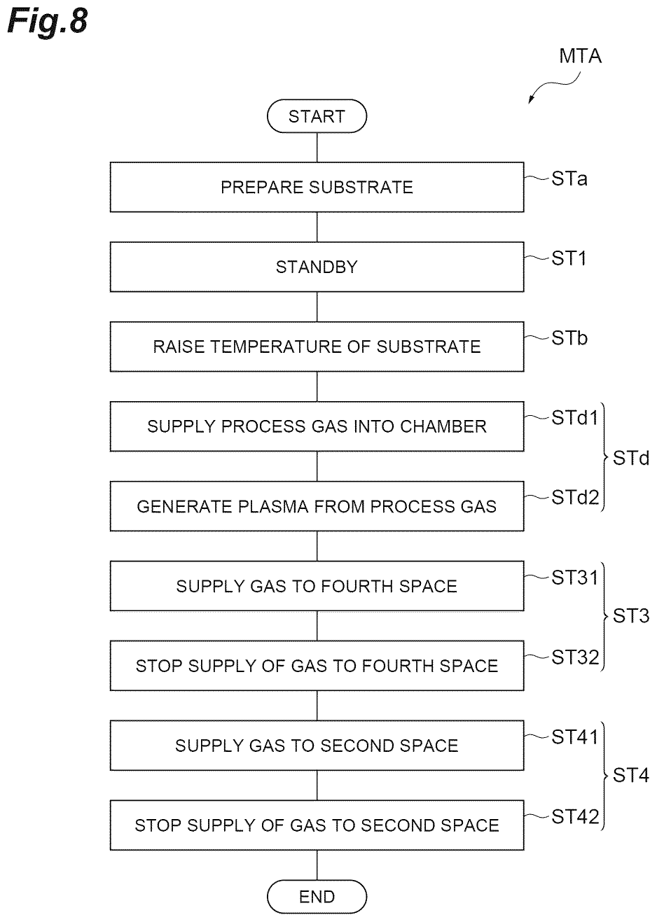

Hereinafter, a substrate processing method according to one exemplary embodiment will be described with reference to FIG. 8. FIG. 8 is a flowchart of the substrate processing method according to one exemplary embodiment. The substrate processing method (hereinafter, referred to as a “method MTA”) shown in FIG. 8 may be executed by the plasma processing system shown in FIG. 1. Hereinafter, a case where the controller 2 or the operator controls each portion of the plasma processing apparatus 1 including the substrate support assembly 11B to execute the substrate processing method with respect to the substrate W will be described as an example.

The method MTA includes step STa, step STb, step STd, and step ST3. The method MTA may include step ST1.

First, step STa is performed. In step STa, the substrate W is prepared on the substrate support 51 in the chamber 10 of the plasma processing apparatus 1. The steps of the method MT performed after step STa are performed in a state where the substrate W is placed on the substrate support 51.

In one embodiment, step ST1 may be performed after step STa and before step STd. In step ST1, the plasma processing apparatus 1 is in a standby state. In step ST1, the power may be supplied to the heater 51c from the power supply controlled by the heater controller HC in a state where the valve 95a and the valve 58a are closed and the heat transfer medium M is not supplied to the tank 56. The power supplied to the heater 51c in step ST1 may be smaller than the power supplied to the heater 51c in step STb described later. In one example, the first power may be supplied to the heater 51c. The temperature of the substrate W on the substrate support 51 may be a first temperature due to the heat generation of the heater 51c.

After step STa, step STb is performed. Step STb may be performed after step ST1. In step STb, the temperature of the substrate W prepared on the substrate support 51 is increased. Step STb includes a step of supplying the power to the heater 51c from the power supply controlled by the heater controller HC in a state where the valve 95a and the valve 58a are closed and the heat transfer medium M is not supplied to the tank 56. The power supplied to the heater 51c in step STb may be greater than the power supplied to the heater 51c in step ST1. In one example, the second power may be supplied to the heater 51c. The second power is greater than the first power. The substrate W on the substrate support 51 may be heated to a second temperature as a target due to the heat generation of the heater 51c. The second temperature is higher than the first temperature.

In step STb, since the heat transfer medium M is not present in the first space 56a of the tank 56, the thermal resistance between the base 50 (second base 53) and the substrate support 51 is large. Therefore, the temperature of the substrate support 51 can be adjusted to a temperature apart from the temperature of the base 50. As a result, the temperature of the substrate W on the substrate support 51 is adjusted in a relatively high temperature range.

After step STb, step STd is performed. In step STd, the substrate processing is performed on the substrate W disposed on the substrate support 51. In one example, the plasma processing may be performed in step STd. Step STd includes step STd1 and step STd2. Step STd includes a step of supplying power smaller than the power in step STb to the heater 51c from the power supply controlled by the heater controller HC. In one example, the temperature of the substrate W on the substrate support 51 may be maintained at the second temperature by the heat generation of the heater 51c.

In step STd1 and step STd2, step STd1 is performed first. In step STd1, the process gas is supplied into the chamber 10 from the gas introducer (for example, the showerhead 13). After step STd1, step STd2 is performed. In step STd2, the plasma generator 12 generates the plasma from the process gas in the chamber 10.

After step STd, step ST3 is performed. In step ST3, the heat transfer medium M is supplied to the first space 56a of the tank 56. In step ST3, the temperature of the substrate W disposed on the substrate support 51 is lowered. Step ST3 includes step ST31 and step ST32.

First, step ST31 is performed. In step ST31, the valve 95a is opened. In step ST31, the first gas supply 95 supplies the gas to the fourth space 91b. Since the gas is supplied to the fourth space 91b and the pressure in the fourth space 91b is increased, the piston 92 moves and the volume of the fourth space 91b is increased such that the volume of the third space 91a is decreased. The inside of the third space 91a is pressurized by decreasing the volume of the third space 91a, and the heat transfer medium M in the third space 91a is supplied to the first space 56a via the pipe 93.

In step ST31, the valve 58a may be opened. In step ST31, the first exhauster 58 may exhaust the gas in the second space 56b. Since the gas in the second space 56b is exhausted and the pressure in the second space 56b is decreased, the movable plate 57 moves and the volume of the second space 56b is decreased such that the volume of the first space 56a is increased. The first space 56a is depressurized by increasing the volume of the first space 56a, and the heat transfer medium M in the third space 91a is supplied to the first space 56a via the pipe 93.

After step ST31, step ST32 is performed. In step ST32, the valve 95a is closed. In step ST32, the heat transfer medium M is held in the first space 56a of the tank 56. In step ST32, the supply of the gas to the fourth space 91b by the first gas supply 95 is stopped. In step ST32, the valve 58a may be closed. The exhaust of the gas in the second space 56b by the first exhauster 58 may be stopped.

In step ST3, since the heat transfer medium M is in the first space 56a of the tank 56, the thermal resistance between the base 50 and the substrate support 51 is small. Therefore, the temperature of the substrate support 51 can be adjusted to a temperature close to the temperature of the base 50. As a result, the temperature of the substrate W on the substrate support 51 is adjusted in a relatively low temperature range.

The method MTA may further include step ST4. Step ST4 is performed after step ST3. In step ST4, the heat transfer medium M in the first space 56a of the tank 56 is supplied to the third space 91a. Step ST4 includes step ST41 and step ST42.

First, step ST41 is performed. In step ST41, the valve 59a is opened. In step ST41, the second gas supply 59 supplies the gas to the second space 56b. Since the gas is supplied to the second space 56b and the pressure in the second space 56b is increased, the movable plate 57 moves and the volume of the second space 56b is increased such that the volume of the first space 56a is decreased. The inside of the first space 56a is pressurized by decreasing the volume of the first space 56a, and the heat transfer medium M in the first space 56a is supplied to the third space 91a via the pipe 93.

In step ST41, the valve 96a may be opened. In step ST41, the second exhauster 96 may exhaust the gas in the fourth space 91b. Since the gas in the fourth space 91b is exhausted and the pressure in the fourth space 91b is decreased, the piston 92 moves and the volume of the fourth space 91b is decreased such that the volume of the third space 91a is increased. The third space 91a is depressurized by increasing the volume of the third space 91a, and the heat transfer medium M in the first space 56a is supplied to the third space 91a via the pipe 93.

After step ST41, step ST42 is performed. In step ST42, the valve 59a is closed. In step ST42, the heat transfer medium M is held in the first space 56a of the tank 56. In step ST42, the supply of the gas to the second space 56b by the second gas supply 59 is stopped. In step ST42, the valve 96a may be closed. The exhaust of the gas in the fourth space 91b by the second exhauster 96 may be stopped.

Here, the various exemplary embodiments included in the present disclosure are described in the following [E1] to [E17].

[E1] A substrate support assembly including:
a base including a flow path;
a substrate support on the base; and
a heat transfer medium supply connected to the flow path,
wherein the heat transfer medium supply includes
   a first container configured to store therein a heat transfer medium,
   at least one first pipe connected between a first end of the flow path and the first container,
   a second container,
   at least one second pipe connected between a second end of the flow path and the second container,
   a first gas supply connected to the first container and configured to supply a first gas to the first container to supply the heat transfer medium in the first container to the flow path via the at least one first pipe,
   a second gas supply connected to the second container and configured to supply a second gas to the second container, wherein the heat transfer medium has a specific gravity greater than a specific gravity of the first gas and a specific gravity of the second gas,
      at least one third pipe, and
   a valve connected in series with the at least one third pipe between the first container and the second container.

[E2] The substrate support assembly according to E1, further including:
a first exhauster configured to exhaust a gas from the first container.

[E3] The substrate support assembly according to E1 or E2, further including:
a second exhauster configured to exhaust a gas from the second container.

[E4] The substrate support assembly according to any one of E1 to E3 wherein,
the heat transfer medium supply further includes a valve connected in series with the at least one first pipe between the first end and the first container.

[E5] The substrate support assembly according to any one of E1 to E4 wherein,
the heat transfer medium supply further includes a valve connected in series with the at least one second pipe between the second end and the second container.

[E6] The substrate support assembly according to any one of E1 to E5 wherein,
the first container is below the second container.

[E7] The substrate support assembly according to any one of E1 to E6,
the heat transfer medium is a liquid metal.

[E8] The substrate support assembly according to any one of E1 to E7 wherein,
at least one of an inner surface of the first container, an inner surface of the at least one first pipe, and an inner surface of the flow path includes resin or ceramic.

[E9] The substrate support assembly according to any one of E1 to E8 wherein,
the heat transfer medium is a first heat transfer medium,
the first container is configured to store therein a second heat transfer medium, the second heat transfer medium having a specific gravity smaller than a specific gravity of the first heat transfer medium and greater than a specific gravity of each of the first gas and the second gas,
the heat transfer medium supply further includes
   at least one fourth pipe, and
   a valve connected in series with the at least one fourth pipe between the first end and the first container, and
a position at which the at least one fourth pipe is connected to the first container is above a position at which the at least one first pipe is connected to the first container.

[E10] A substrate support assembly including:
a base including a tank;
a movable plate configured to separate an inner space of the tank into a first space and a second space, and configured to move between the first space and the second space along a direction in which the first space and the second space are arranged;
a substrate support on the base;
a heat transfer medium supply connected to the first space; and
an exhauster configured to exhaust a gas from the second space,
wherein
the heat transfer medium supply includes:
   a cylinder;
   a piston configured to separate an inner space of the cylinder into a third space and a fourth space, and configured to move between the third space and the fourth space along a direction in which the third space and the fourth space are arranged; and
   a pipe connected between the third space and the first space,
the third space is configured to store therein a heat transfer medium, and
the piston is configured to move to decrease a volume of the third space to supply the heat transfer medium in the third space to the first space via the pipe.

[E11] The substrate support assembly according to E10 wherein,
the heat transfer medium supply further includes a gas supply connected to the fourth space, and
the gas supply is configured to supply a gas to the fourth space to move the piston to decrease the volume of the third space by increasing a volume of the fourth space.

[E12] The substrate support assembly according to E11 wherein,
the exhauster includes a first exhauster,
the heat transfer medium supply further includes a second exhauster configured to exhaust the gas in the fourth space, and
the second exhauster is configured to exhaust the gas from the fourth space for supplying the heat transfer medium in the first space to the third space via the pipe, and configured to move the piston to increase the volume of the third space by decreasing the volume of the fourth space.

[E13] The substrate support assembly according to E11 or E12 wherein,
the gas supply includes a first gas supply,
the substrate support assembly further comprises a second gas supply connected to the second space,
the movable plate is configured to move to decrease a volume of the first space to supply the heat transfer medium in the first space to the third space via the pipe, and
the second gas supply is configured to supply a gas to the second space and configured to move the movable plate to decrease the volume of the first space by increasing a volume of the second space.

[E14] The substrate support assembly according to any one of E10 to E13 wherein,
the first space and the second space are arranged in a vertical direction,
the movable plate is configured to move in the vertical direction,
the base includes at least one conduit extending downward in the tank from a top surface of the tank,
the movable plate has at least one through-hole into which the at least one conduit is inserted, and
the movable plate includes a plurality of seal members including
   a seal member between a side surface of the movable plate and an inner surface of the tank and
   at least one seal member between at least one inner surface that defines the at least one through-hole and a side surface of the at least one conduit.

[E15] The substrate support assembly according to any one of E10 to E14,
wherein the heat transfer medium is a liquid metal.

[E16] The substrate support assembly according to E10 or E15, further including:
a base member; and
an insulator on the base member,
wherein the base is supported on the base member via the insulator,
wherein the heat transfer medium supply is between the base and the base member.

[E17] A substrate processing apparatus including:
a chamber; and
the substrate support assembly according to any one of E1 to E16, configured to support a substrate in the chamber.

[E18] A substrate processing method performed in a substrate processing apparatus, the substrate processing apparatus including:
a chamber;
a substrate support assembly configured to support a substrate in the chamber;
a heater in a substrate support of the substrate support assembly;
a heater controller electrically connected to the heater;
a gas introducer configured to introduce a process gas into the chamber, and
a plasma generator configured to generate plasma from the process gas in the chamber,
the substrate support assembly including
   a base including a flow path,
   the substrate support on the base, and
   a heat transfer medium supply connected to the flow path, and
wherein the heat transfer medium supply includes
   a first container configured to store therein a first heat transfer medium and a second heat transfer medium,
   at least one first pipe connected between a first end of the flow path and the first container,
   a first valve connected in series with the at least one first pipe between the first end of the flow path and the first container,
   a second container,
   at least one second pipe connected between a second end of the flow path and the second container,
   a second valve connected in series with the at least one second pipe between the second end of the flow path and the second container,
   a first gas supply connected to the first container and configured to supply a first gas to the first container to supply the first heat transfer medium from the first container to the flow path via the at least one first pipe,
   a first exhauster configured to exhaust a gas from the first container,
   a second gas supply connected to the second container and configured to supply a second gas to the second container, the second heat transfer medium having a specific gravity smaller than a specific gravity of the first heat transfer medium and greater than a specific gravity of each of the first gas and the second gas,
   a second exhauster configured to exhaust a gas from the second container,
   at least one third pipe,
   a third valve connected in series with the at least one third pipe between the first container and the second container,
   at least one fourth pipe connected to the first container above a position at which the at least one first pipe is connected to the first container, and
   a fourth valve connected in series with the at least one fourth pipe between the first end and the first container,
the substrate processing method including:
preparing a substrate on the substrate support;
raising a temperature of the substrate after the preparing a substrate;
adjusting the temperature of the substrate to a temperature for substrate processing on the substrate after the raising a temperature of the substrate;
performing the substrate processing on the substrate after the raising a temperature of the substrate;
lowering the temperature of the substrate after the performing the substrate processing on the substrate; and
recovering at least the second heat transfer medium from the second container after the lowering the temperature of the substrate,
wherein the raising a temperature of the substrate includes supplying power to the heater from the heater controller in a state where the first valve, the second valve, the third valve, and the fourth valve are closed and at least the first heat transfer medium and the second heat transfer medium are not supplied to the flow path,
the adjusting the temperature of the substrate and the performing the substrate processing on the substrate include supplying power smaller than the power in the raising a temperature of the substrate to the heater from the heater controller during the adjusting the temperature of the substrate and the performing the substrate processing on the substrate,
the adjusting the temperature of the substrate includes, for supplying the second heat transfer medium to the flow path,
   opening the second valve and the fourth valve,
   performing exhaust of the gas in the second container by the second exhauster and supply of the first gas to the first container by the first gas supply after the opening the second valve and the fourth valve,
   closing the second valve and the fourth valve after the performing exhaust of the gas in the second container, and
   stopping the exhaust by the second exhauster and the supply of the first gas to the first container by the first gas supply after the performing exhaust of the gas in the second container,
the performing the substrate processing on the substrate includes
   supplying the process gas into the chamber from the gas introducer, and
   generating plasma from the process gas in the chamber by the plasma generator,
the lowering the temperature of the substrate includes, for supplying the first heat transfer medium to the flow path,
   opening the first valve and the second valve,
   performing exhaust of the gas in the second container by the second exhauster and supply of the first gas to the first container by the first gas supply after the opening the first valve and the second valve,
   closing the first valve and the second valve after the performing exhaust of the gas in the second container, and
   stopping the exhaust of the gas by the second exhauster and the supply of the first gas to the first container by the first gas supply after the performing exhaust of the gas in the second container, and
the recovering at least the second heat transfer medium from the second container includes opening the third valve in a state where the first valve, the second valve, and the fourth valve are closed.

[E19] A substrate processing method executed in a substrate processing apparatus, the substrate processing apparatus including:
a chamber;
a substrate support assembly configured to support a substrate in the chamber;
a heater in a substrate support of the substrate support assembly;
a heater controller electrically connected to the heater;
a gas introducer configured to introduce a process gas into the chamber; and
a plasma generator configured to generate plasma from the process gas in the chamber,
the substrate support assembly including
   a base including a tank,
   a movable plate configured to separate an inner space of the tank into a first space and a second space and configured to move between the first space and the second space along a direction in which the first space and the second space are arranged,
   the substrate support on the base,
   a heat transfer medium supply connected to the first space, and
   an exhauster configured to exhaust a gas from the second space,
wherein
the heat transfer medium supply includes
   a cylinder,
   a piston configured to separate an inner space of the cylinder into a third space and a fourth space, and configured to move between the third space and the fourth space along a direction in which the third space and the fourth space are arranged,
   a pipe connected between the third space and the first space, and
   a gas supply connected to the fourth space,
the third space is configured to store therein a heat transfer medium,
the piston is configured to move to decrease a volume of the third space to supply the heat transfer medium in the third space to the first space via the pipe, and
the gas supply is configured to supply a gas to the fourth space, and configured to move the piston to decrease the volume of the third space by increasing a volume of the fourth space,
the substrate processing method including:
preparing a substrate on the substrate support;
raising a temperature of the substrate after the preparing a substrate;
performing the substrate processing on the substrate after the raising a temperature of the substrate; and
lowering the temperature of the substrate after the performing the substrate processing on the substrate,
wherein the raising a temperature of the substrate includes supplying power to the heater from the heater controller in a state where the heat transfer medium is not supplied to the first space,
the performing the substrate processing on the substrate includes
   supplying the process gas into the chamber from the gas introducer, and
   generating plasma from the process gas in the chamber by the plasma generator,
the lowering the temperature of the substrate includes
   supplying the gas to the fourth space by the gas supply, and
   stopping supply of the gas to the fourth space by the gas supply after the supplying the gas to the fourth space.

From the foregoing description, it will be understood that various embodiments of the present disclosure have been described herein for purposes of illustration, and that various modifications may be made without departing from the scope and gist of the present disclosure. Accordingly, the various embodiments disclosed herein are not intended to be limiting, with the true scope and gist being indicated by the appended claims.

What is claimed is:

1. A substrate support assembly comprising:
a base including a flow path;
a substrate support on the base; and
a heat transfer medium supply connected to the flow path,
wherein the heat transfer medium supply includes
a first container configured to store therein a heat transfer medium,
at least one first pipe connected between a first end of the flow path and the first container,
a second container,
at least one second pipe connected between a second end of the flow path and the second container,
a first gas supply connected to the first container and configured to supply a first gas to the first container to supply the heat transfer medium in the first container to the flow path via the at least one first pipe,
a second gas supply connected to the second container and configured to supply a second gas to the second container, wherein the heat transfer medium has a specific gravity greater than a specific gravity of the first gas and a specific gravity of the second gas,
at least one third pipe, and
a valve connected in series with the at least one third pipe between the first container and the second container.

2. The substrate support assembly according to claim 1, further comprising:
a first exhauster configured to exhaust a gas from the first container.

3. The substrate support assembly according to claim 1, further comprising:
a second exhauster configured to exhaust a gas from the second container.

4. The substrate support assembly according to claim 1, wherein
the heat transfer medium supply further includes a valve connected in series with the at least one first pipe between the first end and the first container.

5. The substrate support assembly according to claim 1, wherein
the heat transfer medium supply further includes a valve connected in series with the at least one second pipe between the second end and the second container.

6. The substrate support assembly according to claim 1, wherein
the first container is below the second container.

7. The substrate support assembly according to claim 1, wherein
the heat transfer medium is a liquid metal.

8. The substrate support assembly according to claim 7, wherein
at least one of an inner surface of the first container, an inner surface of the at least one first pipe, and an inner surface of the flow path includes resin or ceramic.

9. The substrate support assembly according to claim 1, wherein
the heat transfer medium is a first heat transfer medium,
the first container is configured to store therein a second heat transfer medium, the second heat transfer medium having a specific gravity smaller than a specific gravity of the first heat transfer medium and greater than a specific gravity of each of the first gas and the second gas,
the heat transfer medium supply further includes
at least one fourth pipe, and
a valve connected in series with the at least one fourth pipe between the first end and the first container, and
a position at which the at least one fourth pipe is connected to the first container is above a position at which the at least one first pipe is connected to the first container.

10. A substrate support assembly comprising:
a base including a tank;
a movable plate configured to separate an inner space of the tank into a first space and a second space, and configured to move between the first space and the second space along a direction in which the first space and the second space are arranged;
a substrate support on the base;
a heat transfer medium supply connected to the first space; and
an exhauster configured to exhaust a gas from the second space,
wherein
the heat transfer medium supply includes:
a cylinder;
a piston configured to separate an inner space of the cylinder into a third space and a fourth space, and configured to move between the third space and the fourth space along a direction in which the third space and the fourth space are arranged; and
a pipe connected between the third space and the first space,
the third space is configured to store therein a heat transfer medium, and
the piston is configured to move to decrease a volume of the third space to supply the heat transfer medium in the third space to the first space via the pipe.

11. The substrate support assembly according to claim 10, wherein
the heat transfer medium supply further includes a gas supply connected to the fourth space, and
the gas supply is configured to supply a gas to the fourth space to move the piston to decrease the volume of the third space by increasing a volume of the fourth space.

12. The substrate support assembly according to claim 11, wherein
the exhauster includes a first exhauster,
the heat transfer medium supply further includes a second exhauster configured to exhaust the gas in the fourth space, and
the second exhauster is configured to exhaust the gas from the fourth space for supplying the heat transfer medium in the first space to the third space via the pipe, and configured to move the piston to increase the volume of the third space by decreasing the volume of the fourth space.

13. The substrate support assembly according to claim 11, wherein
the gas supply includes a first gas supply,
the substrate support assembly further comprises a second gas supply connected to the second space,
the movable plate is configured to move to decrease a volume of the first space to supply the heat transfer medium in the first space to the third space via the pipe, and
the second gas supply is configured to supply a gas to the second space and configured to move the movable plate to decrease the volume of the first space by increasing a volume of the second space.

14. The substrate support assembly according to claim 10, wherein
the first space and the second space are arranged in a vertical direction,
the movable plate is configured to move in the vertical direction,
the base includes at least one conduit extending downward in the tank from a top surface of the tank,
the movable plate has at least one through-hole into which the at least one conduit is inserted, and
the movable plate includes a plurality of seal members including
a seal member between a side surface of the movable plate and an inner surface of the tank and
at least one seal member between at least one inner surface that defines the at least one through-hole and a side surface of the at least one conduit.

15. The substrate support assembly according to claim 10,
wherein the heat transfer medium is a liquid metal.

16. The substrate support assembly according to claim 7, further comprising:
a base member; and
an insulator on the base member,
wherein the base is supported on the base member via the insulator,
wherein the heat transfer medium supply is between the base and the base member.

17. A substrate processing apparatus comprising:
a chamber; and
the substrate support assembly according to claim 1, configured to support a substrate in the chamber.

18. A substrate processing method performed in a substrate processing apparatus, the substrate processing apparatus comprising:
a chamber;
a substrate support assembly configured to support a substrate in the chamber;
a heater in a substrate support of the substrate support assembly;
a heater controller electrically connected to the heater;
a gas introducer configured to introduce a process gas into the chamber, and
a plasma generator configured to generate plasma from the process gas in the chamber,
the substrate support assembly including
a base including a flow path,
the substrate support on the base, and
a heat transfer medium supply connected to the flow path, and
wherein the heat transfer medium supply includes
a first container configured to store therein a first heat transfer medium and a second heat transfer medium,
at least one first pipe connected between a first end of the flow path and the first container,
a first valve connected in series with the at least one first pipe between the first end of the flow path and the first container,
a second container,
at least one second pipe connected between a second end of the flow path and the second container,
a second valve connected in series with the at least one second pipe between the second end of the flow path and the second container,
a first gas supply connected to the first container and configured to supply a first gas to the first container to supply the first heat transfer medium from the first container to the flow path via the at least one first pipe,
a first exhauster configured to exhaust a gas from the first container,
a second gas supply connected to the second container and configured to supply a second gas to the second container, the second heat transfer medium having a specific gravity smaller than a specific gravity of the first heat transfer medium and greater than a specific gravity of each of the first gas and the second gas,
a second exhauster configured to exhaust a gas from the second container,
at least one third pipe,
a third valve connected in series with the at least one third pipe between the first container and the second container,
at least one fourth pipe connected to the first container above a position at which the at least one first pipe is connected to the first container, and
a fourth valve connected in series with the at least one fourth pipe between the first end and the first container,
the substrate processing method comprising:
preparing a substrate on the substrate support;
raising a temperature of the substrate after the preparing a substrate;
adjusting the temperature of the substrate to a temperature for substrate processing on the substrate after the raising a temperature of the substrate;
performing the substrate processing on the substrate after the raising a temperature of the substrate;
lowering the temperature of the substrate after the performing the substrate processing on the substrate; and
recovering at least the second heat transfer medium from the second container after the lowering the temperature of the substrate,
wherein the raising a temperature of the substrate includes supplying power to the heater from the heater controller in a state where the first valve, the second valve, the third valve, and the fourth valve are closed and at least the first heat transfer medium and the second heat transfer medium are not supplied to the flow path,
the adjusting the temperature of the substrate and the performing the substrate processing on the substrate include supplying power smaller than the power in the raising a temperature of the substrate to the heater from the heater controller during the adjusting the temperature of the substrate and the performing the substrate processing on the substrate,
the adjusting the temperature of the substrate includes, for supplying the second heat transfer medium to the flow path,
opening the second valve and the fourth valve,
performing exhaust of the gas in the second container by the second exhauster and supply of the first gas to the first container by the first gas supply after the opening the second valve and the fourth valve,
closing the second valve and the fourth valve after the performing exhaust of the gas in the second container, and
stopping the exhaust by the second exhauster and the supply of the first gas to the first container by the first gas supply after the performing exhaust of the gas in the second container,
the performing the substrate processing on the substrate includes
supplying the process gas into the chamber from the gas introducer, and
generating plasma from the process gas in the chamber by the plasma generator,
the lowering the temperature of the substrate includes, for supplying the first heat transfer medium to the flow path,
opening the first valve and the second valve,
performing exhaust of the gas in the second container by the second exhauster and supply of the first gas to the first container by the first gas supply after the opening the first valve and the second valve,
closing the first valve and the second valve after the performing exhaust of the gas in the second container, and
stopping the exhaust of the gas by the second exhauster and the supply of the first gas to the first container by the first gas supply after the performing exhaust of the gas in the second container, and
the recovering at least the second heat transfer medium from the second container includes opening the third valve in a state where the first valve, the second valve, and the fourth valve are closed.
